(19) United States
(12) Patent Application Publication
(10) Pub. No.: US 2010/0224322 A1
(43) Pub. Date: Sep. 9, 2010

(54) ENDPOINT DETECTION FOR A REACTOR CHAMBER USING A REMOTE PLASMA CHAMBER

(75) Inventors: ZHIFENG SUI, Fremont, CA (US); Matthew F. Davis, Felton, CA (US)

Correspondence Address: LAW OFFICE OF ROBERT M. WALLACE, 2112 EASTMAN AVENUE, SUITE 102, VENTURA, CA, 93003, US

(73) Assignee: Applied Materials, Inc., Santa Clara, CA (US)

(21) Appl. No.: 12/699,677

(22) Filed: Feb. 3, 2010

Related U.S. Application Data
(60) Provisional application No. 61/209,174, filed on Mar. 3, 2009.

(51) Int. Cl. C23F 1/08; B05C 11/00; H01L 21/3065

(52) U.S. Cl. 156/345.25; 118/665

(57) ABSTRACT

An analysis chamber coupled to a processing chamber includes an actively switchable capacitive-inductive coupling apparatus providing excitation in a capacitively coupled mode and an inductively coupled mode.

### CROSS-REFERENCE TO RELATED APPLICATIONS

This application claims the benefit of U.S. Provisional Application Ser. No. 61/209,174, filed Mar. 3, 2009 entitled ENDPOINT DETECTION FOR A REACTOR CHAMBER USING A REMOTE PLASMA CHAMBER, by Zhifeng Sui, et al.

### BACKGROUND

Optical emission spectroscopy (OES) has been used for monitoring and analyzing the characteristics of a plasma within a reactor chamber during plasma processing of a workpiece. Such OES systems are disclosed in U.S. Pat. Nos. 5,288,367, issued Feb. 22, 1994; 5,308,414, issued May 3, 1994; and 4,859,277, issued Aug. 22, 1989. OES has also been used for endpoint detection in plasma processes. OES endpoint detection in plasma processing is disclosed in U.S. Pat. Nos. 5,986,747, issued Nov. 16, 1999 and 6,366,346, issued Apr. 2, 2002. Several new chemistries used in photoresist strip processes “quench” the useable spectra as the strip process progresses and thus make it impossible to analyze the process by OES. Additionally, some wafer processing methods do not use plasma; i.e., they are non-ionizing processes. These non-ionizing processes cannot be monitored by OES.

U.S. Pat. No. 5,986,747 discloses a small remote plasma chamber coupled to receive reactants from the main reactor chamber. In one method, the remote plasma chamber is used for OES endpoint detection for a semiconductor process, such as etching. The OES endpoint detection may be performed in the remote plasma chamber using plasma source power independent of a main process chamber. Endpoint detection of a plasma process for etching an exposed oxide film constituting not more than 1% of the total surface area of the wafer is challenging. Some endpoint detection systems work well when the exposed oxide film thickness is less than 0.5% of the total wafer surface area when certain chemistries are used. For instance, in cases in which a CF4/CHF3/Ar chemistry is used, a conventional endpoint detection system is sufficient for endpoint detection purpose. However, the detection limit increases to about 2% of exposed film to total wafer surface area when C4F6/O2/Ar chemistry is used. In certain applications, the C4F6 chemistry is used for oxide etch and such chemistry offers better etch selectivity to a photoresist layer. Therefore, there is a need for better sensitivity in an endpoint detection system.

### SUMMARY

An analysis chamber coupled to a processing chamber is configured to determine an endpoint of a process in the processing chamber. An optical window is provided through which the interior of said analysis chamber is viewable by a detection apparatus. In accordance with one embodiment, the analysis chamber includes an actively switchable capacitive-inductive coupling apparatus providing excitation in a capacitively coupled mode and an inductively coupled mode.

In accordance with another embodiment, the analysis chamber includes power applicator apparatus which may be an external RF coil antenna or a pair of external opposing electrodes. In a further embodiment, the analysis chamber includes an annular separation apparatus at the boundary between a main chamber portion of the analysis chamber and a sub-chamber containing the optical window. The annular separation apparatus may includes an annular-shaped permanent magnet outside of said analysis chamber or an annular barrier inside said analysis chamber defining a center opening facing said optical window.

In accordance with a related embodiment, sub-chamber RF excitation apparatus is provided for coupling RF power into the sub-chamber for continuous cleaning of the optical window. A sub-chamber cleaning gas supply may provided a gas suitable for cleaning of the optical window.

### BRIEF DESCRIPTION OF THE DRAWINGS

So that the manner in which the exemplary embodiments of the present invention are attained and can be understood in detail, a more particular description of the invention, briefly summarized above, may be had by reference to the embodiments thereof which are illustrated in the appended drawings. It is to be appreciated that certain well known processes are not discussed herein in order to not obscure the invention.

FIG. 1 depicts a schematic of an exemplary semiconductor wafer processing system;

FIG. 2 depicts a block diagram of an exemplary system controller of the processing system in FIG. 1.

FIG. 3 depicts a block diagram of an exemplary system in accordance with the present invention.

FIGS. 4A and 4B depict an exemplary analysis chamber in accordance with a first embodiment.

FIG. 5 depicts an analysis chamber in accordance with another embodiment.

FIG. 6 depicts an analysis chamber in accordance with yet another embodiment.

FIG. 7 depicts an analysis chamber in accordance with a further embodiment.

FIG. 8 depicts an analysis chamber in accordance with a yet further embodiment.

FIG. 9 depicts an analysis chamber in accordance with a still further embodiment.

FIG. 10 depicts an analysis chamber assembly that includes a multiple aperture isolation ring and cooling of the coil antenna.

FIG. 11 depicts an embodiment including a switched plasma ignition feature in the coil antenna.

FIG. 12 depicts a system controller in accordance with one embodiment.

To facilitate understanding, identical reference numerals have been used, where possible, to designate identical elements that are common to the figures. It is contemplated that elements and features of one embodiment may be beneficially incorporated in other embodiments without further recitation. It is to be noted, however, that the appended drawings illustrate only exemplary embodiments of this invention and are therefore not to be considered limiting of its scope, for the invention may admit to other equally effective embodiments.

### DETAILED DESCRIPTION

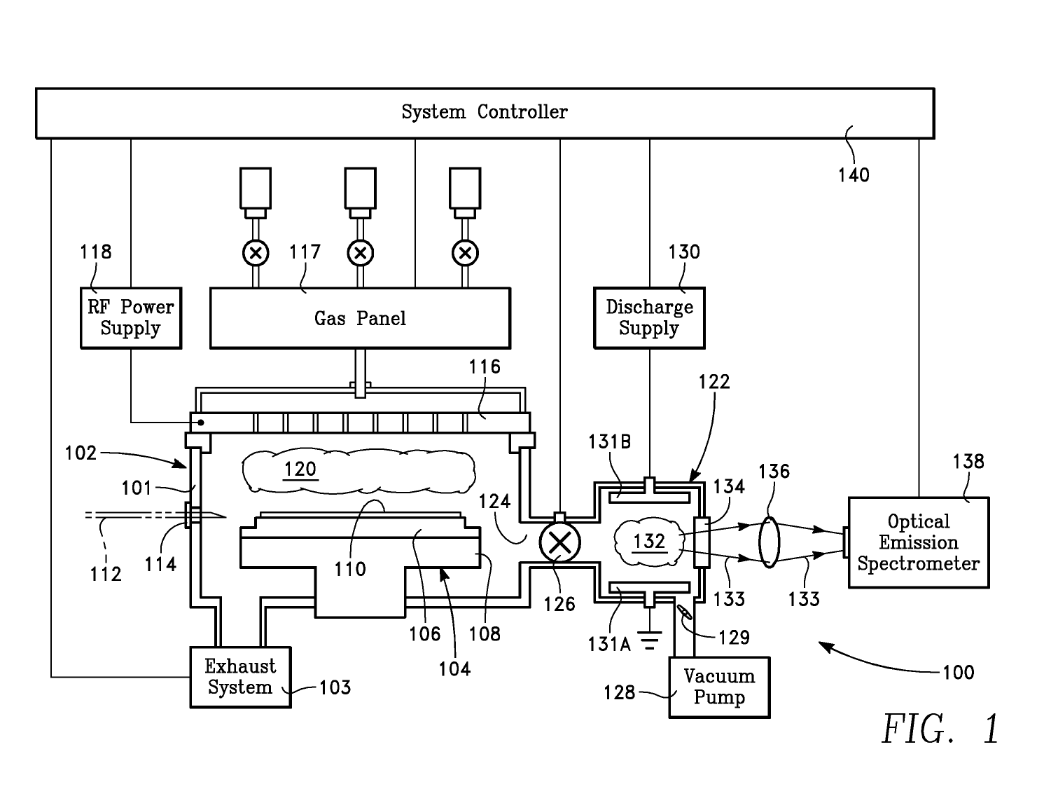

An OES endpoint detection system will now be described. A semiconductor processing system 100 is depicted in FIG. 1. The system 100 can be a reactor used to process a wafer or other substrate. The system 100 includes a main process chamber 102 and an analysis chamber 122. The main chamber 102 comprises a set of walls 101 defining an enclosed volume wherein a wafer support 104 supports a semiconductor wafer 110. The main chamber 102 can be any type of process chamber suitable for performing wafer process steps such as etch, physical vapor deposition (PVD), chemical vapor deposition (CVD), plasma enhanced chemical vapor deposition (PECVD), photoresist stripping, wafer cleaning and the like. An exhaust system 103 regulates a pressure within the main chamber 102. The wafer support 104 comprises a susceptor 106 mounted to a pedestal 108. The pedestal 108 is typically fabricated from a metal such as aluminum. The susceptor 106 is typically fabricated from a dielectric material such as a polyimide or ceramic. A substrate such as semiconductor wafer 110 rests on the susceptor 106 during processing. The susceptor 106 includes components such as resistive heaters, bias electrodes or electrostatic chuck electrodes. The latter can be implemented using any number of chucking electrodes and any type of chucking electrode structure including monopolar, bipolar, tripolar, interdigitated, zonal and the like. Similarly, any number or arrangement of heaters can be used including a single heater, or two or more heaters can be used for zoned heating and the like.

A robot arm 112, shown in phantom, transfers the wafer 110 in and out of the main chamber 102 through a slit valve 114. The main chamber 102 has a showerhead 116 for introducing process gases from a gas panel 117. For an etch process, the showerhead 116 can be either grounded to serve as an anode or powered by a radio frequency power supply. A radio frequency (RF) power supply 118 is connected to the showerhead 116. Alternatively or in addition, RF power can be supplied to the pedestal 108 or to an electrode (not shown) within the susceptor 106. RF power supplied by the power supply 118 maintains a plasma 120 within the main chamber 102 for processing the wafer 110.

A small analysis chamber 122 is connected to a port 124 on the main chamber 102. The analysis chamber 122 is in fluid connection to the processing environment of the main chamber 102 but shielded from the plasma 120 using a means of blocking cross diffusion of charged species. Preferably, the analysis chamber 122 is made from a material that is chemically inert to the byproducts being analyzed such as anodized aluminum. Alternatively, an analysis chamber 122 made of ceramic or similar material can be used for analysis of byproducts that are corrosive to metals. A sample of gas from the main chamber 102 (including byproducts of the process occurring in the main chamber) enters the analysis chamber 122 through the port 124. A valve 126, connected to the port 124, and a supplemental exhaust system including a vacuum pump 128 and an exhaust valve 129 regulate the residence time of byproducts in the analysis chamber 122. In the analysis chamber 122, the gaseous byproducts can be analyzed separately from the plasma 120 in the main chamber 102. The concentration of byproducts in the analysis chamber depends upon the process taking place in the main chamber 102.

In the analysis chamber 122, the byproducts are excited by energy from an excitation source comprising, for example, a discharge supply 130 that applies RF voltage between two electrodes 131A and 131B. A suitable discharge supply 130 is manufactured by ENI of Rochester, N.Y. The RF voltage sustains a discharge 132 that excites the gaseous byproducts in the analysis chamber. Alternatively, the byproducts can be excited by an alternating current (AC) antenna-solenoid coil, a direct current (DC) discharge, or ultraviolet (UV) radiation, or laser, alone or as an assisting source. The excited gaseous byproducts de-excite and produce radiation such as light 133. The light 133 can be any form of electromagnetic radiation such as infrared, ultraviolet or visible light. The light 133 is coupled through a transparent window 134 to a lens 136. The lens 136 focuses the light 133 into an optical analyzer such as an optical emission spectrometer 138. The spectrometer 138 can be a grating monochromator or at least one bandpass photon detector or similar apparatus for detecting the energy content of a particular wavelength of the spectrum of the light 133. A specific bandpass photon detector is disclosed in commonly assigned U.S. Pat. No. 5,995,235, issued Nov. 30, 1999. Useful spectra from the byproducts cannot be quenched by the process in the main chamber 102 because the discharge 132 is separate from the process plasma 120. Furthermore, the discharge 132 in the analysis chamber 122 does not influence the process in the main chamber 102.

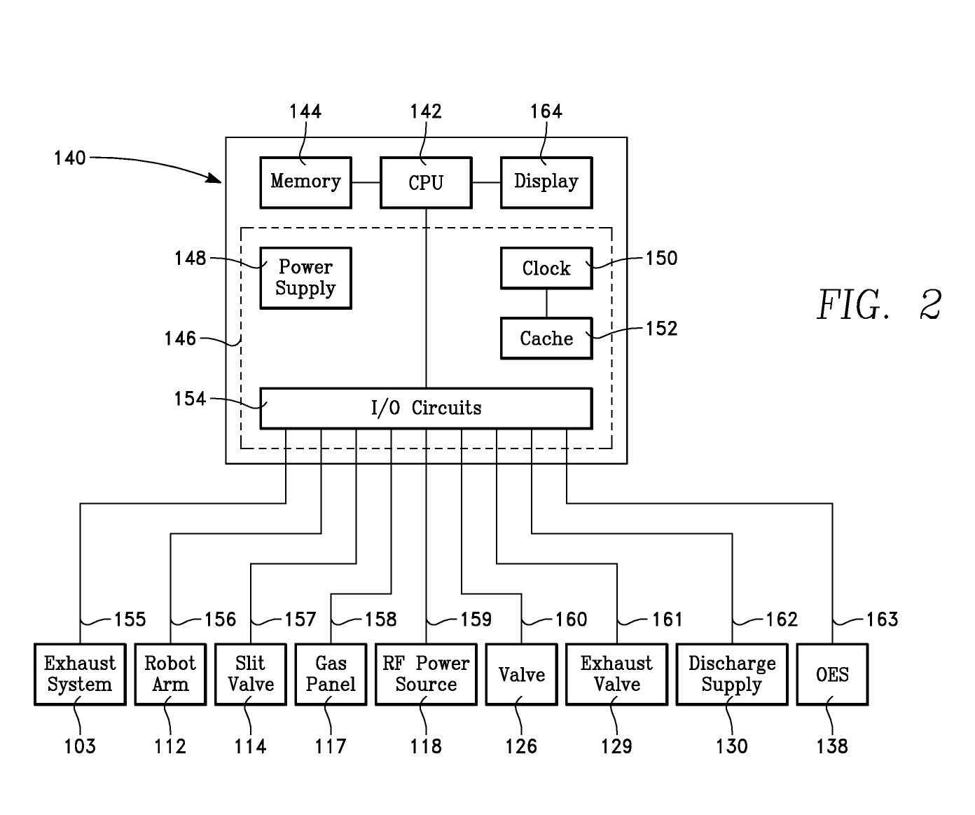

The wafer processing system 100 has a controller 140 that includes hardware to provide the necessary signals to initiate, monitor, regulate, and terminate the processes occurring in the chamber 102. The details of the controller are depicted in the block diagram of FIG. 2. The controller 140 includes a programmable central processing unit (CPU) 142 that is operable with a memory 144 (e.g., RAM, ROM, hard disk and/or removable storage) and well-known support circuits 146 such as power supplies 148, clocks 150, cache 152, input/output (I/O) circuits 154 and the like. More specifically, I/O circuits 154 produce control signals such as control outputs 155, 156, 157, 158, 159, 160, 161, 162 and receive at least one input 163. By executing software stored in the memory 144, the controller 140 produces control outputs 155, 156, 157, 158, 159, 160, 161, and 162 that respectively control the exhaust system 103, the robot arm 112, the slit valve 114, the gas panel 117, the RF power supply 118, the valve 126, the exhaust valve 129 and the discharge supply 130. The controller 140 receives signals such as the input 163 from the OES 138. The controller 140 also includes hardware for monitoring wafer processing through sensors (not shown) in the chamber 102. Such sensors measure system parameters such as wafer temperature, chamber atmosphere pressure, plasma voltage and current. Furthermore, the controller 140 includes at least one display device 164 that displays information in a form that can be readily understood by a human operator. The display device 164 is, for example, a graphical display that portrays system parameters and control icons upon a “touch screen” or light pen based interface.

The system 100 may be controlled using a suitable computer program running on the CPU 142 of the controller 140. The CPU 142 forms a general purpose computer that becomes a specific purpose computer when executing programs. Although the system control is described herein as being implemented in software and executed upon a general purpose computer, those skilled in the art will realize that such control could be implemented using hardware such as an application specific integrated circuit (ASIC) or other hardware circuitry. As such, it should be understood that the system control can be implemented, in whole or in part, in software, hardware or both.

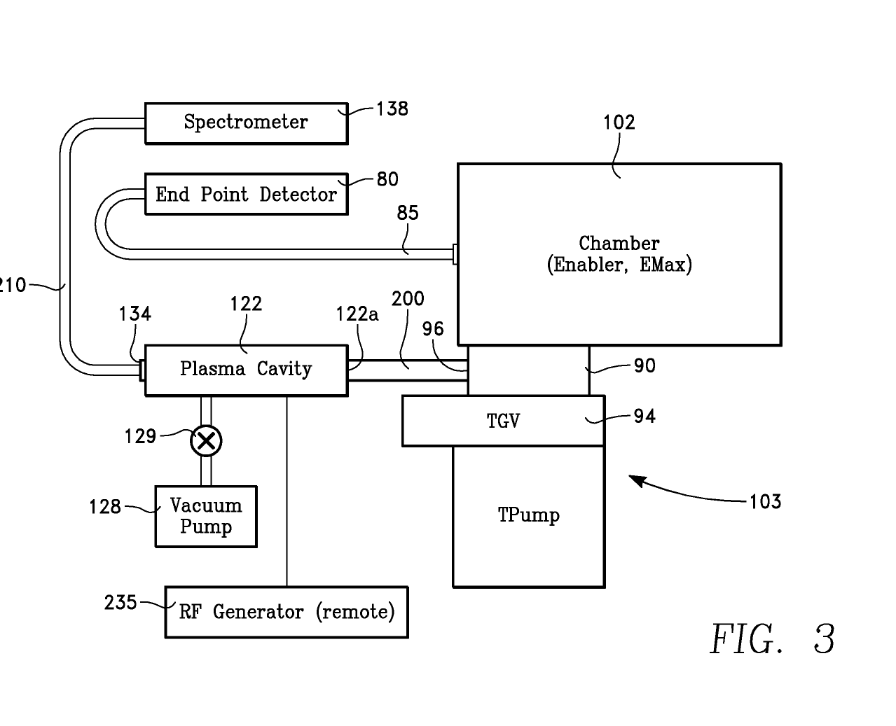

FIG. 3 depicts an OES endpoint detection system in accordance with one embodiment. The system of FIG. 3 includes components described with reference to FIG. 1, including the main chamber 102, the main chamber vacuum pump 103, the analysis chamber 122, the analysis chamber vacuum pump 128, the transparent window 134 and the optical emission spectrometer 138. The main chamber exhaust system 103 is placed below the chamber and pumps through a main exhaust port 90 at the bottom of the main chamber 102. The exhaust system 103 includes a throttle valve 94 that controls the evacuation rate or chamber pressure by regulating gas flow of the exhaust system 103. In the embodiment of FIG. 3, the analysis chamber 122 is coupled to a side opening 96 of the main exhaust port 90 through a connection or inlet 200 coupled to the analysis chamber 122. Optionally, the analysis chamber vacuum pump 128 evacuates the analysis chamber 122 through a valve 129 controlled by the processor. Referring again to FIG. 3, the OES or spectrometer system 138 is optically coupled to the analysis chamber window 134 via a fiber optic cable 210. Other optical coupling may be employed to achieve the same result. A remote RF generator 235 provides plasma source power to the analysis chamber 122. The RF plasma source power from the generator 235 produces a plasma in the analysis chamber 122 from byproducts that enter the analysis chamber 122 through the inlet 200 from the main chamber 102. In one embodiment, the RF generator 235 is configured to provide a variable plasma source power that enables the variable degree of the dissociation of molecules in the analysis chamber. Optionally, a conventional OES monitor or endpoint detector 80 may monitor plasma in the main chamber 102 through an optical fiber 85.

The power output level of the RF generator 235 may be controlled to govern the degree of dissociation of species in the analysis chamber 122 as well as to affect residency time. The residency time may be the time frame during which the dissociated species reside in the chamber. The residency time in the analysis chamber 122 may also be controlled independently by the optional analysis chamber vacuum pump 128 and valve 129. In one embodiment, the residency time of in the analysis chamber 122 is controlled by the dimension of the inlet 200. The degree of dissociation is affected by residency time, and determines the spectra (atomic or molecular) of reactions observed by the OES system 138. The output power level of the RF generator 235, the pump rate of the vacuum pump, the opening size of the valve 129 and the opening size of the inlet 200 are parameters that affect dissociation in the analysis chamber 122. These parameters are set (e.g., by the controller 140) to optimize the OES signal level of wavelengths of interest in determining the process endpoint of a particular process carried out in the main chamber 102.

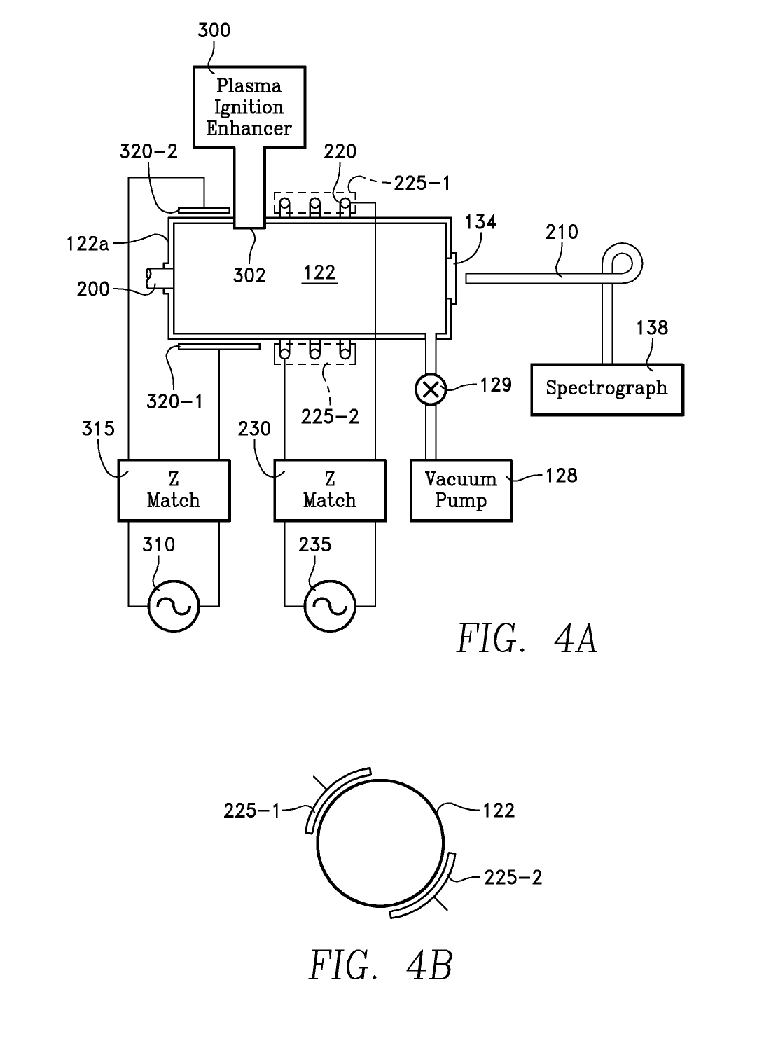

FIG. 4A depicts one embodiment of the analysis chamber 122, in which RF plasma source power is coupled into the analysis chamber using an external inductively coupled source power applicator in the form of a helical coil antenna 220 wound around the outside of the analysis chamber 122. In this embodiment, the analysis chamber 122 may be of a cylindrical shape coaxial with the coil antenna 220. Alternatively, the power applicator may be an external capacitively coupled source power applicator in the form of a pair of external electrodes 225-1, 225-2 outside of the analysis chamber. As shown in FIG. 4B the pair of external electrodes 225-1, 225-2 may be formed as partial cylinders facing one another, both being concentric with and facing the cylindrical analysis chamber 122 and lying on opposite sides of the analysis chamber 122. While a choice may be made to incorporate either the coil antenna 220 or the electrode pair 225-1, 225-2 as the source power applicator, FIG. 4A depicts both the coil antenna 220 and the electrode pair 225-1, 225-2.

The RF power generator 235 is connected through a conventional RF impedance match 230 across the RF source power applicator. The RF power generator 235 is connected through the impedance match 230 across either the coil antenna 220 or across the pair of electrodes 225-2, 225-2, depending upon which type of RF source power applicator is present. FIG. 4A shows the inlet 200 being disposed at an input end 122a of the analysis chamber 122

Plasma ignition at low pressures may be enhanced by a plasma ignition enhancer 300, which may be a source of laser radiation or a source of ultraviolet light that illuminates the interior of the analysis chamber 122 through a window 302. The plasma ignition enhancer 300 may be employed to enhance the dissociation of gaseous species in the analysis chamber 122. Alternatively, plasma ignition may be enhanced by providing an RF generator 310 of an HF or LF frequency (e.g., 13.56 MHz or 2 MHz or less) coupled through an RF impedance match 315 to a pair of electrodes 320-1, 320-2 adjacent the analysis chamber 122.

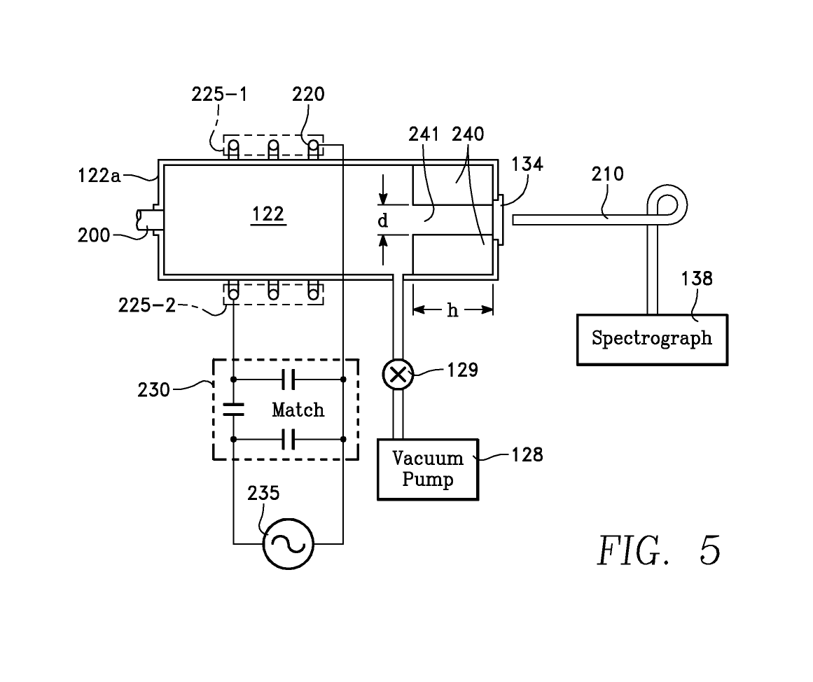

FIG. 5 depicts a modification of the embodiment of FIG. 4A, in which an annular spacer 240 having a high aspect-ratio circular opening 241 surrounds the analysis chamber window 134. The circular opening 241 is in registration with the window 134, and has a sufficiently high aspect ratio (its length h divided by its diameter d) to block plasma byproducts in the analysis chamber 122 from depositing on the interior surface of the window 134. This feature reduces the frequency at which the window 134 must be cleaned or replaced.

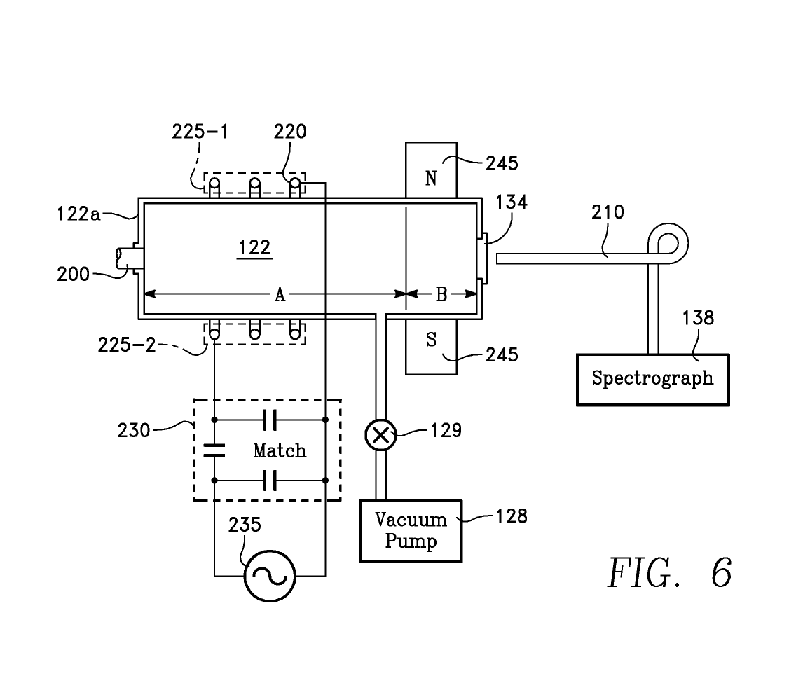

FIG. 6 depicts a modification of the embodiment of FIG. 4A, in which an annular magnet 245 surrounds a short section of the analysis chamber 122 adjacent the window 134. The magnet 245 may be a permanent magnet or an electromagnet providing a D.C. magnetic field. In either case, the magnetic field strength of the magnet 245 is sufficient to block plasma byproducts in the central region of the analysis chamber 122 (the region surrounded by the RF power applicator 220 or 225) from reaching the window 134. This feature reduces the frequency at which the window 134 must be cleaned or replaced. The distance from the input end 122a of the analysis chamber 122 to the magnet 245 is labeled “A” in FIG. 6, while the distance from the magnet 245 to the window 134 is labeled “B” in FIG. 6. The magnet 245 may be placed so close to the window 134 that the ratio of the distances B/A is a small fraction such as about ⅕ to 1/20, or preferably about 1/10.

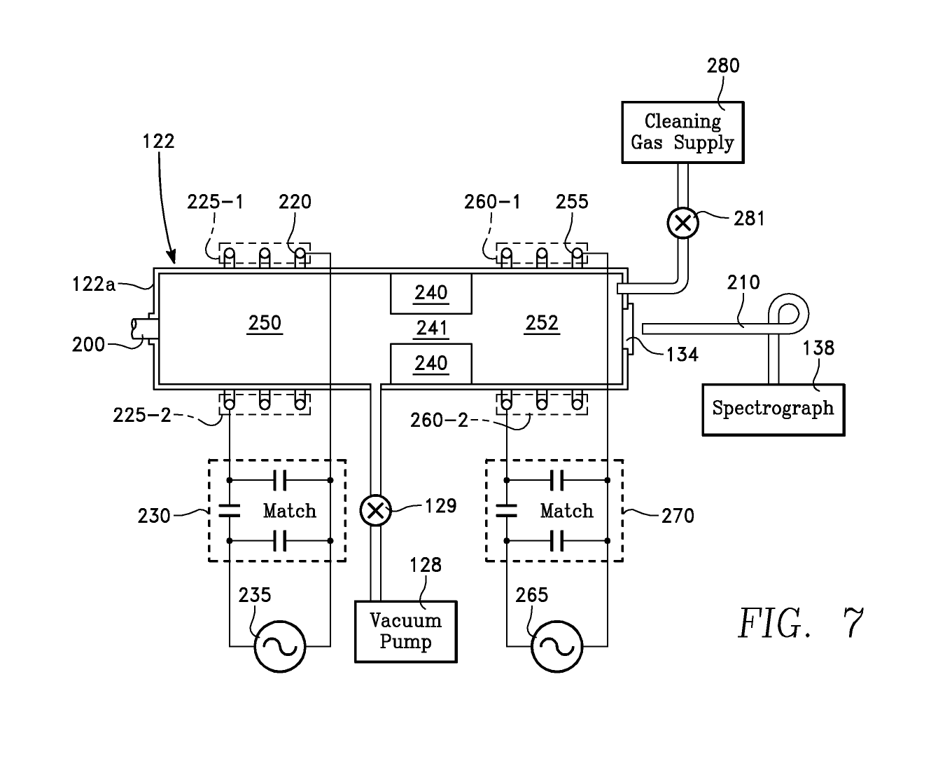

FIG. 7 depicts another embodiment, in which the annular spacer 240 divides the analysis chamber 122 into a primary chamber 250 and a secondary chamber 252. The window 134 is formed on the outer end of the secondary chamber 252. The primary chamber 250 is surrounded by the RF power applicator (namely either the coil antenna 220 or the electrode pair 225-1 and 225-2). A secondary RF power applicator in the form of a coil antenna 255 or pair of electrodes 260-1, 260-2 surrounds a section of the secondary chamber 252. A secondary RF generator 265 is coupled through a secondary RF impedance match 270 to the secondary RF power applicator (namely, either the coil antenna 255 or the pair of electrodes 260-1, 260-2). The secondary RF power generator 265 produces an isolated plasma in the secondary chamber 252 that is free of the plasma byproducts of the primary chamber (or of the main chamber 102 of FIG. 1) that tend to coat or contaminate the window 134. The plasma in the secondary chamber 252 may be formed of a chemistry suitable for cleaning the window 134 or maintaining it clear, such as oxygen. For this purpose, an optional cleaning gas (e.g., oxygen or other cleaning gas) supply 280 may be coupled through a valve 281 to the secondary chamber 252 for plasma cleaning of the interior surface of the window 134. The primary RF generator 235 is set to a power level that determines whether the spectra observed in the primary chamber 250 by the OES apparatus 138 is primarily molecular or atomic. The secondary RF generator 265 is set to a power level that is optimal for keeping the window 134 clean with minimal wear. The power level of the RF generator 235 of the analysis chamber 122 is set of optimize the signal strength of the OES wavelengths of interest for the particular process.

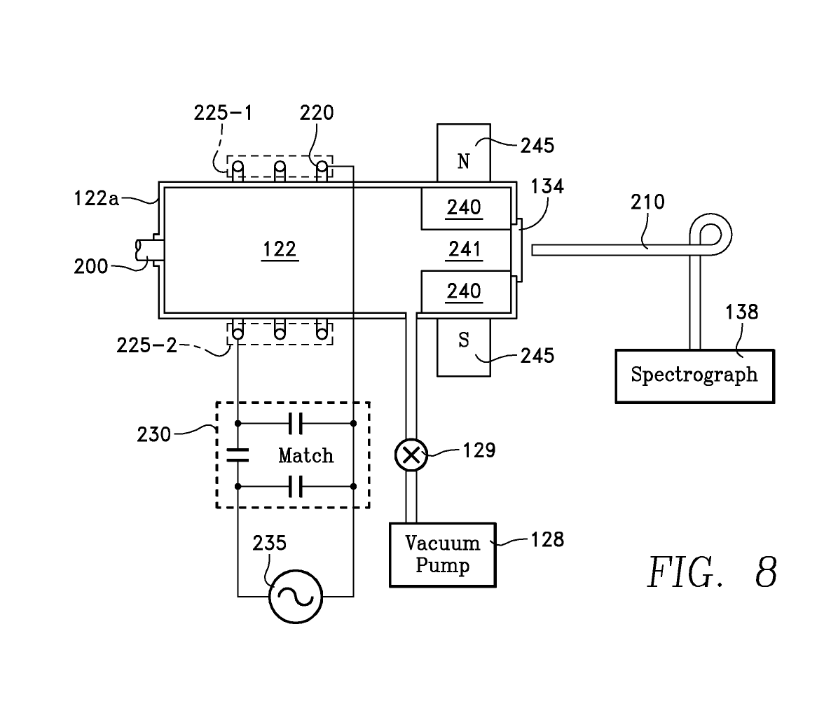

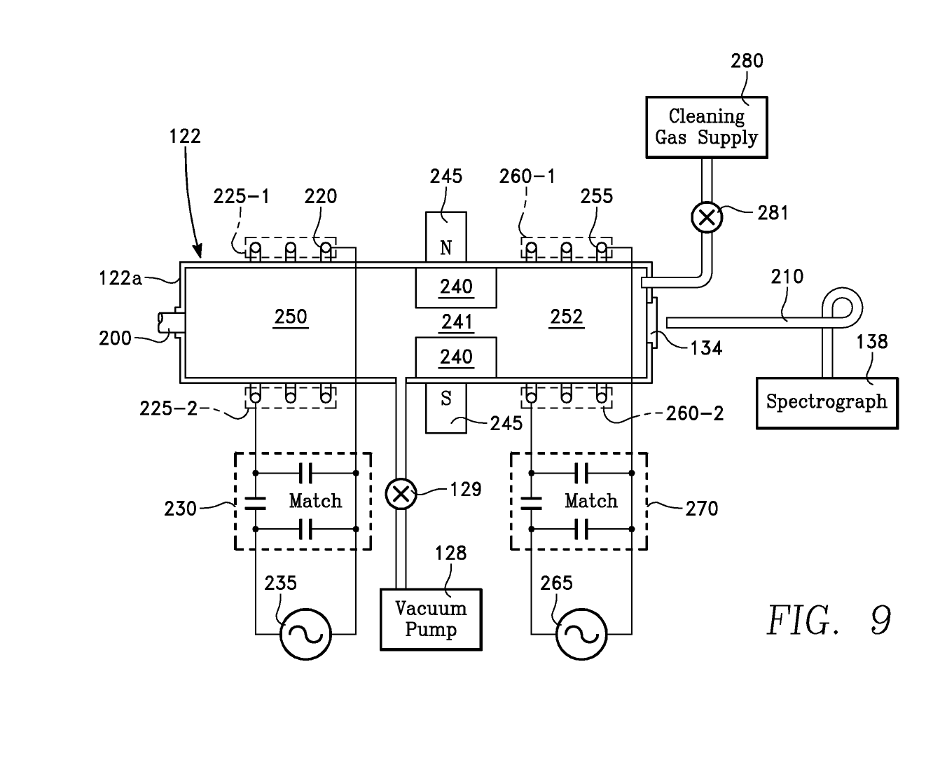

FIG. 8 depicts an embodiment combining the isolation magnet 245 of FIG. 6 with the isolation spacer 240 of FIG. 5. FIG. 9 depicts an embodiment combining the isolation spacer 245 between the primary and secondary chambers 250, 252 of FIG. 7 with the isolation magnet 245 of FIG. 6.

The analysis chamber 122 may be formed using ceramic-metal brazement technology, or alternately, with sapphire-metal brazement technology coupled with sapphire-sapphire eutectic bonding technology. Such material enable the analysis chamber to withstand high temperatures, such as 200 C-300 C. Such high temperature operation maintains interior surfaces in a clean state, free of polymeric residues.

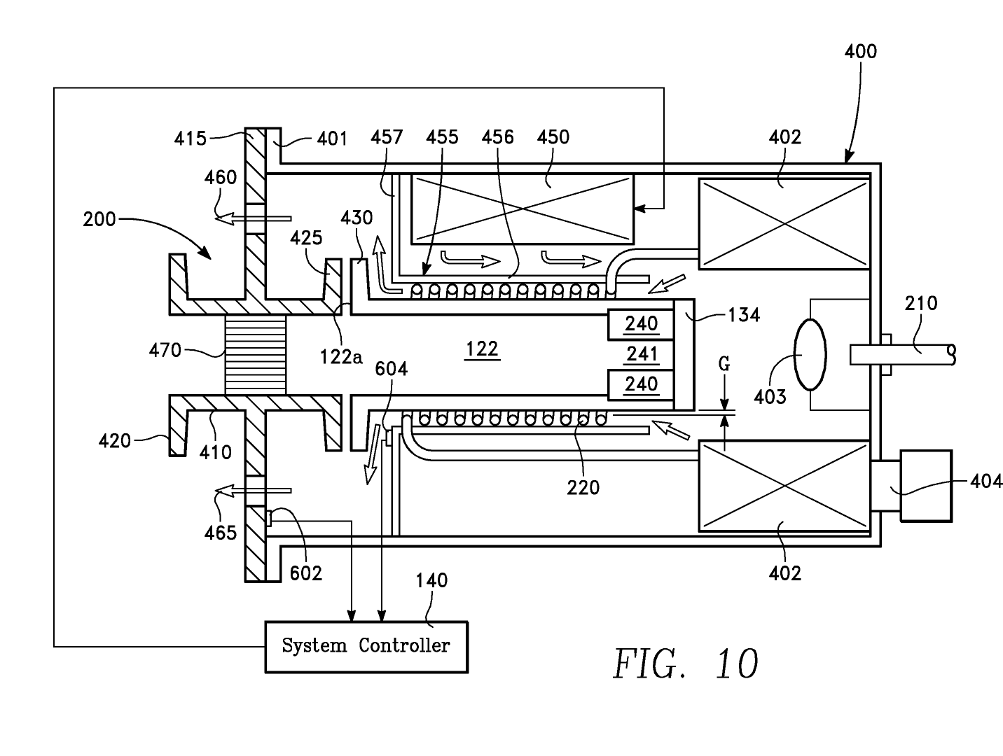

Referring to FIG. 10, an assembly including the analysis chamber 122 includes an external housing 400 having a flange 401 at one end. The external housing 400 supports an annular-shaped RF chassis 402 containing the RF impedance match 230 (of FIG. 4A, for example). The housing 400 further supports a lens 403 disposed between the analysis chamber window 134 and one end of the optical fiber 210 (held in an optical fiber connector, for example). An RF connector 404 of the RF chassis 402 extends through the housing 400. The inlet 200 includes a hollow cylinder 410 having a radially extending circular central flange 415 fastened to the flange 401 of the external housing 400. In addition, input and output flanges 420 and 425 are formed at opposite ends of the hollow cylinder 410. The analysis chamber 122 has a circular flange 430 formed at its input end 122a fastened to the output flange 425 of the hollow cylinder 410. In one embodiment, the flange 420 at the input end of the hollow cylinder 410 may be coupled to the opening 96 of the main chamber exhaust port 90 of FIG. 3, for example.

The housing 400 may further support an air cooling fan assembly 450 and an air duct 455 consisting of a cylindrical wall 456 surrounding the coil antenna 220 and a radial flange 457 fastened to the external housing 400. In one embodiment, an air flow gap labeled “G” in FIG. 10 is formed between the coil antenna 220 and the outer surface of the analysis chamber 122 and air vents 460, 465 are formed in the central flange 415. These features guide air from the cooling fan assembly 450 to flow along the radially outer surface of the wall 456 of the air duct 455 and then along the radially inner surface of the wall 456, which forces the air to flow within the gap G so as to cool the coil antenna 220, before exhausting through the vents 460, 465. A temperature sensor 602 is placed near the air vent 465 and another temperature sensor 604 is placed at the air flow output end of the gap G between the coil 220 and the duct 455. The temperature sensors 602, 604 may have their outputs coupled to a system controller such as the system controller 140 of FIG. 1.

Optionally, a Faraday shield 470 with low resistance to gas diffusion may be placed within the hollow cylinder 410.

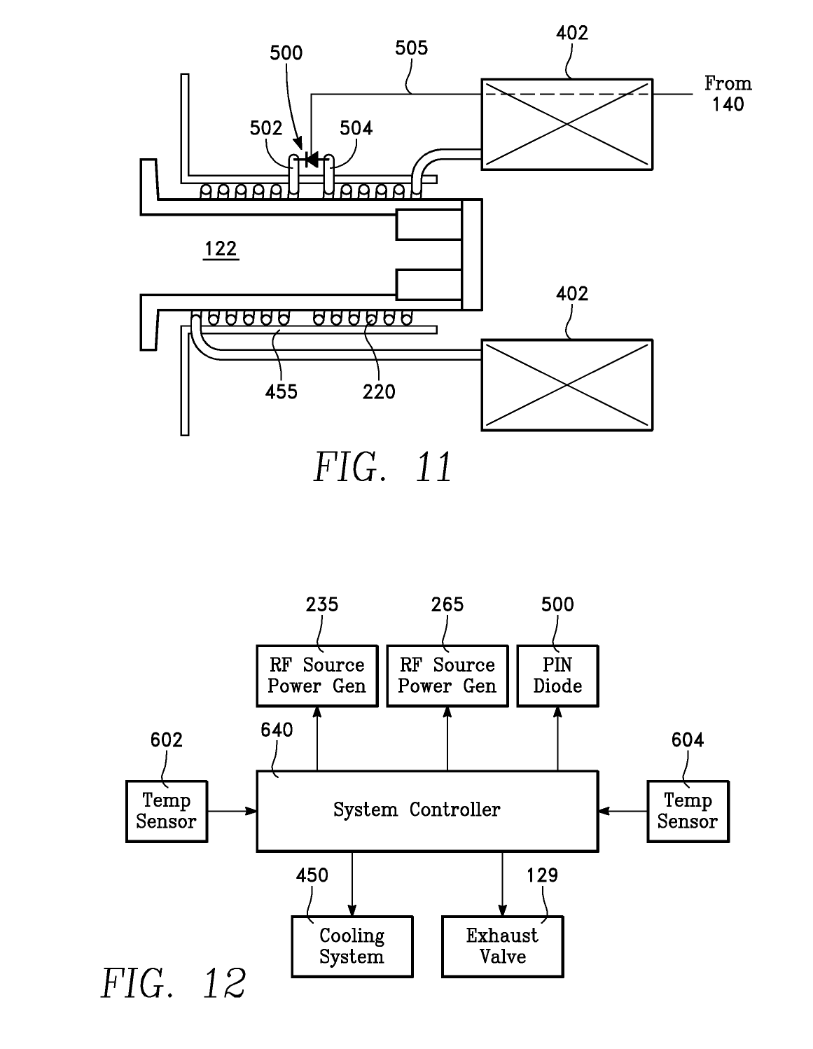

Another embodiment depicted in FIG. 11 facilitates plasma ignition when needed, such as at low gas pressure, ranging from about 4 mTorr to 400 mTorr. This embodiment utilizes the coil antenna 220 as a capacitively coupled power applicator in a first mode during plasma ignition when a plasma is first struck. After plasma ignition, the coil antenna 220 is employed and as an inductively coupled power applicator in a second mode, providing an actively switchable capacitive-inductive coupling of excitation energy. Alternatively, after plasma ignition, the coil antenna may be cycled between the two modes, the duty cycles of each of the two modes controlling process parameters such as dissociation. The embodiment of FIG. 11 is a modification of the embodiment of FIG. 10, in which the conductive winding of the coil antenna 220 is interrupted near its midpoint by an electronically operated switch 500, which may be a PIN diode. The term PIN diode refers to a diode having P-type and N-type semiconductor regions separated by a wide nearly intrinsic semiconductor layer. Coil conductor portions or terminals 502, 504 at the midpoint are connected to opposite ends of the switch 500, the connections to the switch spanning a gap between the two portions or terminals 502, 504. A switching control signal is applied to the switch 500 through a conductor 505 under control of the system controller 140 referred to above with reference to FIG. 1. The conductor 505 may pass through the RF chassis 402 as depicted in FIG. 11.

The switch 500 may be briefly turned off, interrupting the current between the two terminals 502 and 504, to create a high RF voltage drop across the gap between the two terminals 502, 504. This produces a high axial RF electric field in the analysis chamber 122 by capacitive coupling. In one application, the high axial RF electric field facilitates ignition of the plasma. The switch 500 may be turned on (connecting the coil portions 502, 504) to switch the RF coupling to the inductively coupled mode. This latter change may be performed, for example, after plasma ignition. In an alternate mode, the switch 500 may be employed to control dissociation within the analysis chamber 122 during processing of a workpiece in the main chamber, by repetitively switching between the capacitively coupled mode (switch off) and the inductively coupled mode (switch on) and controlling the duty cycles of the two modes. For example, the duty cycle of the capacitively coupled mode may be varied between 0 and 100%, depending upon the degree of dissociation desired.

FIG. 12 depicts a system controller 640, similar to the system controller 140 of FIG. 1, connected to apply integrated system control over the elements of FIGS. 3-11, including the RF source power generator 235 (of FIG. 4A, for example), the secondary RF source power generator 265 (of FIG. 7), the switch or PIN diode 500, the air cooling assembly 450 and, in some embodiments, to the optional analysis chamber exhaust valve 129. In order to control the air cooling assembly 450, the controller 640 receives temperature measurements from the sensors 602, 604. The system controller 640 may be programmed to maintain the analysis chamber 122 at the high temperature (200 C to 300 C) at which interior surfaces such as that of the optical window 134 are maintained free of deposits of materials such as polymers, by activating the air cooling assembly 450 whenever the analysis chamber temperature exceeds a set point, which may be between 200 C and 300 C.

While the foregoing is directed to embodiments of the present invention, other and further embodiments of the invention may be devised without departing from the basic scope thereof, and the scope thereof is determined by the claims that follow.

What is claimed is:

1. An analysis chamber coupled to a processing chamber, said analysis chamber configured to determine an endpoint of a process and comprising an optical window through which the interior of said analysis chamber is viewable by a detection apparatus, and further comprising an actively switchable capacitive-inductive coupling apparatus providing excitation in a capacitively coupled mode and an inductively coupled mode.

2. The analysis chamber of claim 1 further comprising a controller governing said actively switchable capacitive-inductive coupling apparatus, said controller being configured to vary a duty cycle of said capacitive coupling mode between 0 and 100% in accordance with a desired degree of dissociation in said analysis chamber.

3. The analysis chamber of claim 1 further comprising an RF coil antenna configured to be coupled to an RF power source.

4. The analysis chamber of claim 3 further comprising a pair of opposing electrodes at opposing sides of said analysis chamber and configured to be coupled to an RF power source.

5. The analysis chamber of claim 3 wherein said actively switchable capacitive-inductive coupling apparatus comprises a controllable switch connected between adjacent portions of said RF coil antenna.

6. The analysis chamber of claim 5 wherein said controllable switch comprises a PIN diode.

7. The analysis chamber of claim 6 further comprising a programmable controller governing said switch, wherein said programmable controller is programmed to provide capacitive coupling of RF power into said chamber during plasma ignition by turning said switch off, and then turning said switch on after plasma ignition.

8. The analysis chamber of claim 6 wherein said programmable controller is programmed to cycle coupling of RF power from said coil antenna between an inductively coupled mode and a capacitively coupled mode by cycling said switch between on and off states in accordance with a duty cycle.

9. The analysis chamber of claim 8 wherein said controller is programmed to control dissociation in said analysis chamber by controlling said duty cycle.

10. The analysis chamber of claim 1 further comprising an integrated laser or UV source for dissociating gaseous species in said analysis chamber.

11. The analysis chamber of claim 1 wherein said analysis chamber comprises a main chamber portion and a sub-chamber, said optical window located in said sub-chamber, and sub-chamber RF excitation apparatus for coupling RF power into said sub-chamber, said sub-chamber RF excitation apparatus being controllable for continuous cleaning of said optical window.

12. The analysis chamber of claim 11 further comprising a sub-chamber cleaning gas supply coupled to said sub-chamber, and containing a gas suitable for cleaning of the optical window.

13. The analysis chamber of claim 11 further comprising a plasma confinement magnet adjacent a boundary between said main chamber portion and said sub-chamber.

14. The analysis chamber of claim 13 wherein said plasma confinement magnet is a permanent magnet.

15. The analysis chamber of claim 11 further comprising an annular barrier within said analysis chamber at a boundary between said main chamber portion and said sub-chamber.

16. The analysis chamber of claim 1 wherein said analysis chamber comprises a main chamber portion and a sub-chamber, said optical window located in said sub-chamber, and a plasma confinement magnet adjacent a boundary between said main chamber portion and said sub-chamber.

17. The analysis chamber of claim 16 wherein said plasma confinement magnet is a permanent magnet.

18. The analysis chamber of claim 16 further comprising an annular barrier within said analysis chamber at a boundary between said main chamber portion and said sub-chamber.

19. An analysis chamber coupled to a processing chamber and comprising:
an optical window through which the interior of said analysis chamber is viewable by a detection apparatus;
power applicator apparatus comprising at least one of:
(a) an RF coil antenna external of and concentric with said analysis chamber and capable of being coupled to an RF power source, or
(b) a pair of opposing electrodes at opposing external sides of and concentric with said analysis chamber and configured to be coupled to an RF power source; and
wherein said analysis chamber comprises a main chamber portion and a sub-chamber, said optical window located in said sub-chamber, and annular separation apparatus concentric with a boundary between said main chamber portion and said sub-chamber, said annular separation apparatus comprising at least one of:
(a) an annular-shaped permanent magnet outside of said analysis chamber, or
(b) an annular barrier inside said analysis chamber defining a center opening facing said optical window.

20. The analysis chamber of claim 19 further comprising:
sub-chamber RF excitation apparatus for coupling RF power into said sub-chamber, said sub-chamber RF excitation apparatus being controllable for continuous cleaning of said optical window.

21. The analysis chamber of claim 20 further comprising a sub-chamber cleaning gas supply coupled to said sub-chamber, and containing a gas suitable for cleaning of the optical window.

22. The analysis chamber of claim 19 wherein said analysis chamber is coupled to a vacuum exhaust port of said processing chamber.
